(19) United States
(12) Patent Application Publication
(10) Pub. No.: US 2026/0026121 A1
(43) Pub. Date: Jan. 22, 2026

(54) CHIP STRUCTURE AND SEMICONDUCTOR PACKAGE INCLUDING THE SAME

(71) Applicant: SAMSUNG ELECTRONICS CO., LTD., SUWON-SI (KR)

(72) Inventors: JUNG HUA CHANG, Suwon-si (KR); JING CHENG LIN, Suwon-si (KR)

(21) Appl. No.: 19/045,795

(22) Filed: Feb. 5, 2025

(30) Foreign Application Priority Data
Jul. 19, 2024 (KR) 10-2024-0095888

(51) Int. Cl. H10F 39/00; G02B 6/34; H01L 23/00; H01L 23/538; H01L 25/16; H10F 39/95

(52) U.S. Cl. CPC H10F 39/8063; G02B 6/34; H01L 24/08; H01L 25/167; H10F 39/95; H01L 23/5385; H01L 2224/08145; H10F 39/804

(57) ABSTRACT

A chip structure including: a photonic integrated circuit (PIC) chip; an electronic integrated circuit (EIC) chip disposed on the PIC chip; and an optical block disposed on the PIC chip, spaced apart from the EIC chip in a horizontal direction, and configured to transfer optical signals to the PIC chip.

### CROSS-REFERENCE TO RELATED APPLICATION

This application claims priority under 35 U.S.C. § 119 to Korean Patent Application No. 10-2024-0095888, filed on Jul. 19, 2024, in the Korean Intellectual Property Office, the disclosure of which is incorporated by reference herein in its entirety.

### Technical Field

The inventive concept relates to a chip structure and a semiconductor package including the chip structure, specifically a semiconductor package including a photonic integrated circuit chip structure.

### Discussion of Related Art

With the rapid advancement of the electronics industry and increasing user demand, electronic devices are becoming increasingly miniaturized and lightweight. Consequently, semiconductor packages used in electronic devices have also become more compact and lightweight, necessitating higher integration of semiconductor devices.

To enable multi-functional devices, semiconductor packages incorporating various integrated circuits, such as memory chips or logic chips, mounted on a package substrate are being developed. Notably, with the recent surge in data traffic in fields such as data centers and communication infrastructure, research on semiconductor packages featuring photonic integrated circuits is actively progressing.

### SUMMARY

The inventive concept provides a high efficiency optical engine and a semiconductor package including this highly efficient optical engine.

Furthermore, the inventive concept provides a semiconductor package with a photonic integrated circuit designed to minimize light loss.

It will be understood by those of ordinary skill in the art that the objectives and effects of the inventive concept are not limited to the descriptions above. Additional objectives and advantages will become more apparent from the following detailed description.

According to an embodiment of the inventive concept, there is provided a chip structure including: a photonic integrated circuit (PIC) chip; an electronic integrated circuit (EIC) chip disposed on the PIC chip; and an optical block disposed on the PIC chip, spaced apart from the EIC chip in a horizontal direction, and configured to transfer optical signals to the PIC chip.

According to an embodiment of the inventive concept, there is provided a semiconductor package including: a first package substrate; a second package substrate disposed on the first package substrate; a semiconductor chip disposed on the second package substrate; and a chip structure disposed on the second package substrate and spaced apart from the semiconductor chip in a horizontal direction, wherein the chip structure includes: a PIC chip; an EIC chip disposed on the PIC chip; and an optical block disposed on the PIC chip, spaced apart from the EIC chip in the horizontal direction, and configured to transfer optical signals to the PIC chip, and the second package substrate electrically connects the semiconductor chip and the chip structure to the first package substrate.

According to an embodiment of the inventive concept, there is provided a semiconductor package including: a package substrate; a semiconductor chip disposed on the package substrate; and a chip structure arranged on the package substrate and spaced apart from the semiconductor chip in a horizontal direction, wherein the chip structure includes: a PIC chip; an EIC chip disposed on the PIC chip; and an optical block disposed on the PIC chip, spaced apart from the EIC chip in the horizontal direction, and configured to transfer optical signals to the PIC chip.

According to an embodiment of the inventive concept, there is provided a chip structure including: a PIC chip; an EIC chip disposed on the PIC chip; an optical block disposed on the PIC chip, spaced apart from the EIC chip in a horizontal direction, and configured to transfer optical signals to the PIC chip; and an insulating layer located between the optical block and the PIC chip, the insulating layer comprising a grating coupler configured to control a direction of the optical signals incident through the optical block and guide the optical signals into a waveguide formed in the PIC chip.

### BRIEF DESCRIPTION OF THE DRAWINGS

Embodiments of the inventive concept will be more clearly understood from the following detailed description taken in conjunction with the accompanying drawings in which:

FIG. 1 is a plan view schematically showing a semiconductor package according to an embodiment;

FIG. 2 is a cross-sectional view schematically showing the semiconductor package taken along line A-A′ of FIG. 1;

FIG. 3 is a cross-sectional view schematically showing a chip structure according to an embodiment;

FIG. 4 is an enlarged view schematically showing part EX of FIG. 3;

FIG. 5 is a cross-sectional view schematically showing a chip structure according to an embodiment;

FIG. 6 is a cross-sectional view schematically showing a semiconductor package according to an embodiment;

FIG. 7 is a cross-sectional view schematically showing a semiconductor package according to an embodiment;

FIG. 8 is a cross-sectional view schematically showing a semiconductor package according to an embodiment; and

FIGS. 9, 10, 11, 12, 13, 14, 15, 16 and 17 are diagrams schematically showing processes in a method of manufacturing a chip structure according to FIG. 3.

### DETAILED DESCRIPTION OF THE EMBODIMENTS

Hereinafter, one or more embodiments of the inventive concept will be described in detail with reference to the accompanying drawings. For clarity, like reference numerals denote the same elements in the drawings, and repetitive detailed descriptions thereof are omitted.

The inventive concept focuses on a semiconductor package that integrates photonic and electronic circuits for efficient signal processing in miniaturized devices. At its core is a chip structure comprising a Photonic Integrated Circuit (PIC) chip, an Electronic Integrated Circuit (EIC) chip, and an optical block. The PIC chip handles optical signals, the EIC chip interfaces between optical and electronic functionalities, and the optical block, horizontally spaced apart from the EIC chip, minimizes light loss while transferring optical signals to the PIC chip. By embedding over 98% of the optical path within the optical block, the design reduces reflection and maximizes signal efficiency.

Additionally, the chip structure incorporates a micro-lens and waveguide for precise optical signal direction and alignment. Advanced bonding techniques, such as hybrid or oxide bonding, enable seamless integration of the components. The package is adaptable, featuring support for various substrates like silicon interposers or redistribution layers, making it suitable for high-demand applications in data centers and communication infrastructure. This innovative design addresses the need for high-performance, compact, and multifunctional devices, offering a solution for the growing demands of modern electronics.

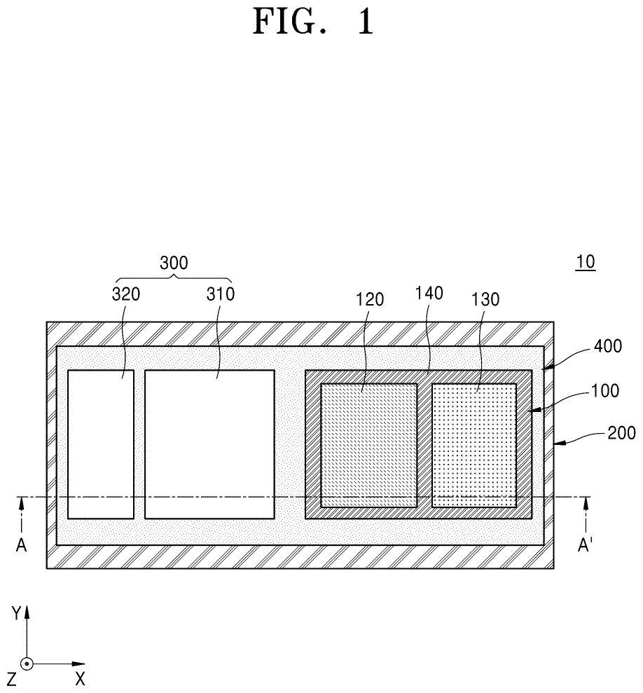

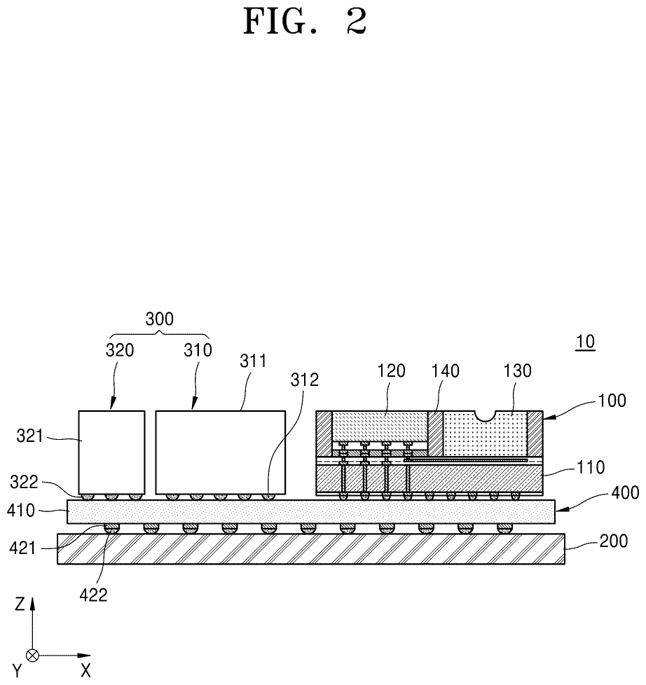

FIG. 1 is a plan view schematically showing a semiconductor package 10 according to an embodiment. FIG. 2 is a cross-sectional view schematically showing the semiconductor package 10 taken along line A-A′ of FIG. 1.

Referring to FIGS. 1 and 2, the semiconductor package 10 may include a chip structure 100, a first package substrate 200, a semiconductor chip 300, and a second package substrate 400. The semiconductor package 10 may communicate with an external device via optical signals.

Hereinafter, unless otherwise specified, a direction parallel to an upper surface of the first package substrate 200 is referred to as a first horizontal direction (X-direction), a direction perpendicular to the upper surface of the first package substrate 200 is referred to as a vertical direction (Z-direction), and a direction perpendicular to the first horizontal direction (X-direction) and the vertical direction (Z-direction) is referred to as a second horizontal direction (Y-direction).

In some embodiments, the first package substrate 200 may be a printed circuit board (PCB) including a core insulating layer including at least one material selected from a phenol resin, an epoxy resin, and polyimide.

The second package substrate 400 may be disposed on the first package substrate 200. The semiconductor chip 300 and the chip structure 100 may be mounted on an upper surface of the second package substrate 400. A lower surface of the second package substrate 400 may face the first package substrate 200. The second package substrate 400 may be disposed to overlap the chip structure 100 and the semiconductor chip 300 in the vertical direction (Z-direction) above the first package substrate 200. The second package substrate 400 may electrically connect the semiconductor chip 300 to the chip structure 100. Additionally, the second package substrate 400 may electrically connect the semiconductor chip 300 and the chip structure 100 to the first package substrate 200.

In some embodiments, the second package substrate 400 may be a silicon interposer, where a substrate 410 includes silicon, and a through-via is a through silicon via (TSV). However, the inventive concept is not limited to this configuration. For example, the second package substrate 400 may alternatively be a glass interposer, where the substrate 410 includes glass, and the through-via is a through glass via (TGV). For example, the second package substrate 400 may be electrically connected to the first package substrate 200 via connection pads 421 and connection terminals 422.

Additionally, in some embodiments, the second package substrate 400 may be a redistribution structure including a redistribution pattern and a redistribution insulating layer surrounding the redistribution pattern.

The redistribution insulating layer may include an insulating material, e.g., a photo-imageable dielectric (PID) resin. In some embodiments, the redistribution insulating layer may further include an inorganic filler. Furthermore, the redistribution insulating layer may have a multi-layered structure, with the redistribution pattern arranged in each layer.

The redistribution pattern may include a redistribution line pattern extending in the horizontal direction, and a redistribution via pattern extending vertically (Z-direction) from the redistribution line pattern. The redistribution line pattern may be disposed on at least one of the upper or lower surfaces of the redistribution insulating layer, or embedded within the redistribution insulating layer. The redistribution via pattern may be connected to a portion of the redistribution line pattern after passing through the redistribution insulating layer.

The redistribution pattern may include a conductive material, for example, copper (Cu), aluminum (Al), argentum (Ag), tin (Sn), aurum (Au), nickel (Ni), lead (Pb), titanium (Ti), or an alloy thereof.

The semiconductor chip 300 may be disposed on the second package substrate 400. According to the embodiments, at least one semiconductor chip 300 may be mounted on the second package substrate 400.

In some embodiments, a first semiconductor chip 310 and a second semiconductor chip 320 may be disposed on the second package substrate 400. For example, the first semiconductor chip 310 may be arranged on the second package substrate 400, spaced apart from the chip structure 100 in the first horizontal direction (X-direction). Similarly, the second semiconductor chip 320 may be arranged on the second package substrate 400, spaced apart from the first semiconductor chip 310 in the first horizontal direction (X-direction).

The first semiconductor chip 310 may include a first semiconductor substrate 311 with an active surface on which a semiconductor device is formed, along with a plurality of first connection terminals 312 disposed on the active surface of the first semiconductor substrate 311. The first semiconductor chip 310 may be mounted on the second package substrate 400 via the plurality of first connection terminals 312, with its active surface facing downward.

Similarly, the second semiconductor chip 320 may include a second semiconductor substrate 321 with an active surface on which a semiconductor element is formed, along with a plurality of second connection terminals 322 disposed on the active surface of the second semiconductor substrate 321. The second semiconductor chip 320 may be mounted on the second package substrate 400 via the plurality of second connection terminals 322, with its active surface facing downward.

In some embodiments, a variety of individual devices may be located on the active surfaces of the first semiconductor chip 310 and the second semiconductor chip 320. These devices may include various microelectronic components, such as complementary metal oxide semiconductor (CMOS) devices, metal-oxide semiconductor field effect transistors (MOSFETs), image sensor like system large scale integration (LSI) or CMOS imaging sensors (CIS), micro-electro-mechanical systems (MEMS), active devices, passive devices, and others.

According to some embodiments, the first semiconductor chip 310 may include a logic chip. For example, the first semiconductor chip 310 may include components such as an application processor (AP), a central processing unit (CPU), a graphics processing unit (GPU), a field-programmable gate array (FPGA), a digital signal processor, an encryption processor, a micro-processor, or a micro controller. Additionally, the first semiconductor chip 310 may include a logic chip such as an analog-digital converter (ADC), or an application-specific integrated circuit (ASIC). However, the inventive concept is not limited to these configurations. For example, the first semiconductor chip 310 may also include a memory chip such as a volatile memory (e.g., DRAM) or a non-volatile memory (e.g., ROM or flash memory). The first semiconductor chip 310 may include a system on chip (SOC) or a combination of the aforementioned components.

According to some embodiments, the second semiconductor chip 320 may include a memory chip. For example, the second semiconductor chip 320 may include a volatile memory chip such as dynamic random-access memory (DRAM) or static RAM (SRAM), or a non-volatile memory chip such as phase-change RAM (PRAM), magnetoresistive RAM (MRAM), ferroelectric RAM (FeRAM), or a resistive RAM (RRAM). A plurality of memory chips may be stacked within the second semiconductor chip 320. For example, the second semiconductor chip 320 may be a high-bandwidth memory (HBM) package with stacked memory chips or a wire-bonding memory package. However, the inventive concept is not limited to memory chips. For example, the second semiconductor chip 320 may also include a logic chip, such as an application processor (AP) or other components, including a central processing unit (CPU), a graphics processing unit (CPU), a field-programmable gate array (FPGA), a digital signal processor, an encryption processor, a micro-processor, or a micro controller.

The chip structure 100 may be located on the second package substrate 400 spaced apart from the semiconductor chip 300 in the horizontal direction (X-direction and/or Y-direction). For example, the chip structure 100 may be arranged on the second package substrate 400 with a spacing in the first horizontal direction (X-direction) relative to the semiconductor chip 300. The chip structure 100 may be electrically connected to the semiconductor chip 300 via the second package substrate 400.

The semiconductor package 10 may communicate with an external device using optical signals through the chip structure 100. The chip structure 100 receives an optical signal from the external device, converts it to an electrical signal, and then transmits the converted electrical signal to the semiconductor chip 300 via the second package substrate 400. For example, the chip structure 100 may be referred to as an optical engine. As will be described below, the optical engine is a core component of the semiconductor package, designed to facilitate efficient optical-electronic signal conversion. It comprises a Photonic Integrated Circuit (PIC) chip, an Electronic Integrated Circuit (EIC) chip, and an optical block that directs optical signals to the PIC chip with minimal light loss, leveraging precise waveguides, grating couplers, and micro-lenses for seamless signal processing.

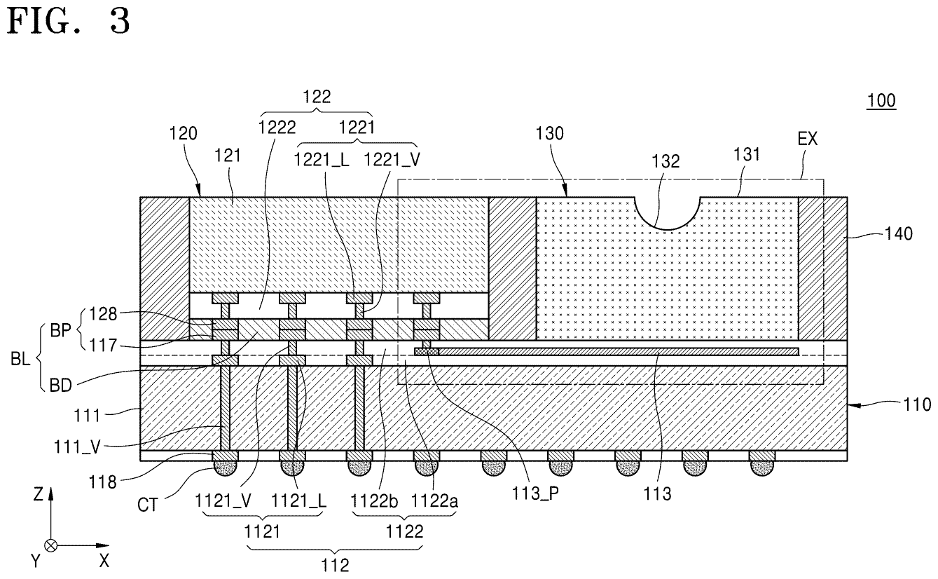

FIG. 3 is a cross-sectional view schematically showing the chip structure 100 according to an embodiment.

Referring to FIG. 3, the chip structure 100 may include a photonic integrated circuit (PIC) chip 110, an electronic integrated circuit (EIC) chip 120, an optical block 130, and a molding layer 140.

The PIC chip 110 may be located on the second package substrate 400 (see FIG. 2). The PIC chip 110 may be spaced apart from the semiconductor chip 300 in the first horizontal direction (X-direction).

For example, a lower pad 118 of the PIC chip 110 may be electrically connected to the second package substrate 400 via a connection terminal CT. However, the connection type between the PIC chip 110 and the second package substrate 400 is not limited thereto.

The PIC chip 110 may include a first substrate 111, a first wiring structure 112, and a waveguide 113. According to the embodiments, the first wiring structure 112 and the waveguide 113 may be located on an upper surface of the first substrate 111. For example, the first substrate 111 may include a through-via 111_V penetrating from the upper surface to the lower surface thereof. In other words, the first substrate 111 may include the through-via 111_V that extends from its upper surface to its lower surface. The through-via 111_V may be electrically connected to the first wiring structure 112.

In some embodiments, the first substrate 111 may include a semiconductor material such as silicon (Si). Additionally, the first substrate 111 may include a semiconductor material such as germanium (Ge).

The first wiring structure 112 may include a first wiring pattern 1121 and a first wiring insulating layer 1122 surrounding the first wiring pattern 1121. The first wiring pattern 1121 may include a first wiring line 1121_L extending in the horizontal direction, and a first wiring via 1121_V extending from the first wiring line 1121_L in the vertical direction (Z-direction). The first wiring pattern 1121 may be electrically connected to the through-via 111_V. For example, the first wiring line 1121_L may be disposed on the PIC chip 110 and make direct contact with the through-via 111_V.

The first wiring insulating layer 1122 may be divided into a lower wiring insulating layer 1122b and an upper wiring insulating layer 1122a. In some embodiments, the lower wiring insulating layer 1122b may be an oxide layer such as silicon oxide. The upper wiring insulating layer 1122a may be a dielectric layer formed of one or more layers including silicon oxide, silicon nitride, or a combination thereof. In some embodiments, the lower wiring insulating layer 1122b and the upper wiring insulating layer 1122a may include the same material.

The PIC chip 110 may further include upper pads 117. The upper pad 117 is located on the upper surface of the first wiring structure 112 and may be electrically connected to the first wiring pattern 1121. For example, the upper pad 117 may make direct contact with the first wiring via 1121_V extending from the first wiring line 1121_L.

The waveguide 113 is a patterned silicon layer and may extend on the lower wiring insulating layer 1122b in the horizontal direction. For example, the waveguide 113 may be embedded in the first wiring insulating layer 1122. For example, the waveguide 113 may be located on the lower wiring insulating layer 1122b and covered by the upper wiring insulating layer 1122a.

In some embodiments, the waveguide 113 may be a silicon waveguide including silicon, and the first wiring insulating layer 1122 may be a buried oxide (BOX) layer. However, the inventive concept is not limited thereto, and the waveguide 113 may be covered by an oxide layer distinct from the first wiring insulating layer 1122.

The waveguide 113 may be connected to a photonic component 113_P. The photonic component 113_P may be connected to an end of the waveguide 113 and overlap with the EIC chip 120 in the vertical direction (Z-direction). The photonic component 113_P may convert an optical signal OS to an electric signal and convert the electric signal to the optical signal OS. In some embodiments, the photonic component 113_P may include a photodetector, a photo-diode, and a modulator.

When the optical signal is input to the chip structure 100, the photodetector may detect an optical signal OS received by the PIC chip 110. The PIC chip 110, using the photodetector, may detect the input optical signal OS and convert the optical signal OS into an electrical signal.

When the chip structure 100 outputs the optical signal OS, the EIC chip 120 may transfer the electrical signal to the modulator. The modulator may input a value corresponding to the received electrical signal to the light emitted from the photo-diode to convert the electrical signal to the optical signal OS. In other words, the modulator may encode the light emitted from the photodiode with a value corresponding to the received electrical signal, thereby converting the electrical signal into the optical signal OS.

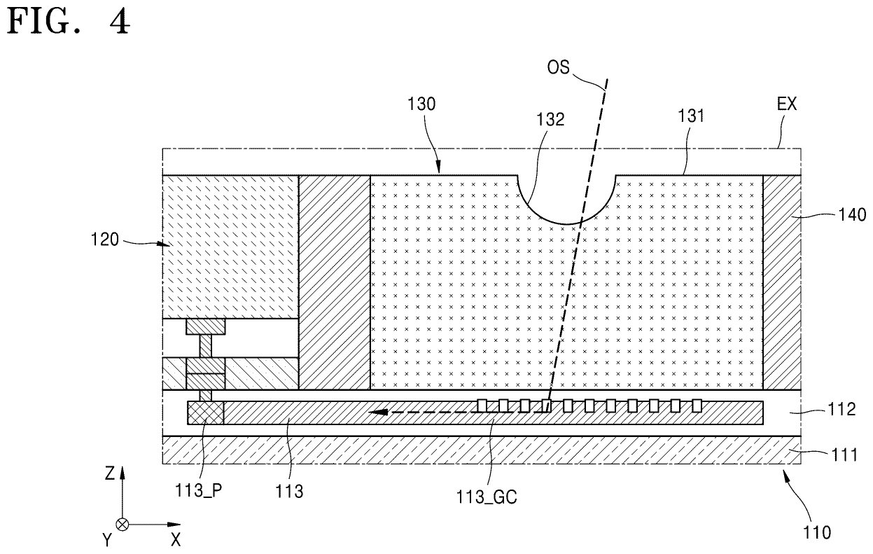

FIG. 4 is an enlarged view schematically showing part EX of FIG. 3.

Referring to FIGS. 3 and 4, a grating coupler 113_GC may be located on one side of the waveguide 113. The PIC chip 110 may receive the optical signal OS from the optical block 130 or transmit the optical signal OS to the optical block 130 via the grating coupler 113_GC. The grating coupler 113_GC may control the direction of the optical signal OS entering through the optical block 130. Specifically, the grating coupler 113_GC may alter the propagation direction of the optical signal OS incident from the optical block 130, directing it to travel along the waveguide 113.

The EIC chip 120 may be located on the PIC chip 110 and configured to interconnect the PIC chip 110 with the semiconductor chip 300. For example, the EIC chip 120 may convert the electrical signal converted by the PIC chip 110 to be compatible with the semiconductor chip 300.

In some embodiments, the width of the EIC chip 120 may be less than that of the PIC chip 110. The PIC chip 110 may be partially covered by the EIC chip 120.

The EIC chip 120 may include a second substrate 121 and a second wiring structure 122. The second substrate 121 of the EIC chip 120 may include an active surface and a non-active surface facing the active surface. The second wiring structure 122 may be formed on the active surface of the second substrate 121.

The second substrate 121 may include a semiconductor material such as SI. Additionally, the second substrate 121 may include a semiconductor material such as Ge.

In some embodiments, the EIC chip 120 may include a plurality of individual devices designed to interface with the PIC chip 110. These devices may be located on the active surface of the second substrate 121. For example, the EIC chip 120 may include components such as CMOS drivers, and trans-impedance amplifiers to manage functions like controlling radio frequency signaling of the PIC chip 110.

The second wiring structure 122 may include a second wiring pattern 1221 and a second wiring insulating layer 1222 surrounding the second wiring pattern 1221. The second wiring pattern 1221 may include a second wiring line 1221_L extending in the horizontal direction, and a second wiring via 1221_V extending from the second wiring line 1221_L in the vertical direction (Z-direction). The second wiring pattern 1221 may be electrically connected to the plurality of individual devices and the lower pad 128.

In some embodiments, the EIC chip 120 may be disposed on the PIC chip 110 with the active surface of the second substrate 121 facing the PIC chip 110. For example, the EIC chip 120 may be arranged in a face-down configuration on the PIC chip 110.

In some embodiments, a bonding layer BL may be located between the EIC chip 120 and the PIC chip 110. The bonding layer BL may include a bonding pad BP and a bonding insulating layer BD surrounding the bonding pad BP. For example, the EIC chip 120 and the PIC chip 110 may be electrically connected to each other via the bonding layer BL located between the EIC chip 120 and the PIC chip 110.

In some embodiments, the bonding pad BP of the bonding layer BL may be formed by diffusion bonding the upper pad 117 of the PIC chip 110 and the lower pad 128 of the EIC chip 120 through the application of heat. Simultaneously, the bonding insulating layer BD may be created by diffusion bonding the insulating layer surrounding the upper pad 117 of the PIC chip 110 with the insulating layer surrounding the lower pad 128 of the EIC chip 120 during the formation of the bonding pad BP.

For example, the EIC chip 120 and the PIC chip 110 may be electrically connected to each other via a hybrid bonding. However, the inventive concept is not limited thereto, and the EIC chip 120 and the PIC chip 110 may be electrically connected using connection terminals such as solder balls or adhesive films, including anisotropic films (ACF), or non-conductive films (NCF).

The optical block 130 may be located on the PIC chip 110. For example, the optical block 130 may be spaced apart from the EIC chip 120 in the first horizontal direction (X-direction) and located on the PIC chip 110. The optical block 130 may be located above the waveguide 113 and the grating coupler 113_GC of the PIC chip 110.

The optical block 130 may include an optical path for transferring the optical signal OS from an external source to the PIC chip 110. This optical path, which directs the external optical signal OS to the PIC chip 110, may primarily be formed within the optical block 130. For example, the chip structure 100 may be designed such that 98% or more of the optical path is formed within the optical block 130.

The optical block 130 may include a main body 131 with a consistent refractive index. For example, the main body 131 may include silicon, glass, or polymer. The consistent refractive index of the main body 131 helps minimize light reflection at the interfaces of materials with different refractive indices as the optical signal OS passes through the main body 131. Because 98% or more of the optical path is formed within the optical block 130, light loss due to reflection is significantly reduced.

The optical block 130 may be bonded to the PIC chip 110 via oxide bonding. However, the inventive concept is not limited thereto, and the optical block 130 may be attached onto the PIC chip 110 via an optical adhesive layer.

At least one micro-lens 132 may be disposed on the upper surface of the main body 131 of the optical block 130. The optical signal OS may be transferred into the main body 131 via the micro-lens 132.

The chip structure 100 may further include the molding layer 140. The molding layer 140 may be located on the PIC chip 110 and may surround the EIC chip 120 and the optical block 130. The molding layer 140 may protect the EIC chip 120 and the optical block 130 from external influences.

In some embodiments, the upper surfaces of the molding layer 140, the EIC chip 120, and the optical block 130 may be coplanar. The upper surface of the EIC chip 120 is exposed to the outside, allowing for efficient dissipation of heat generated by the EIC chip 120.

The molding layer 140 may include an insulating material. According to some embodiments, the molding layer 140 may include PECVD, SiO₂, SiCN, SiON, or polymer. Additionally, the molding layer 140 may include an epoxy resin, a polyimide resin, etc. For example, the molding layer 140 may include an epoxy molding compound (EMC).

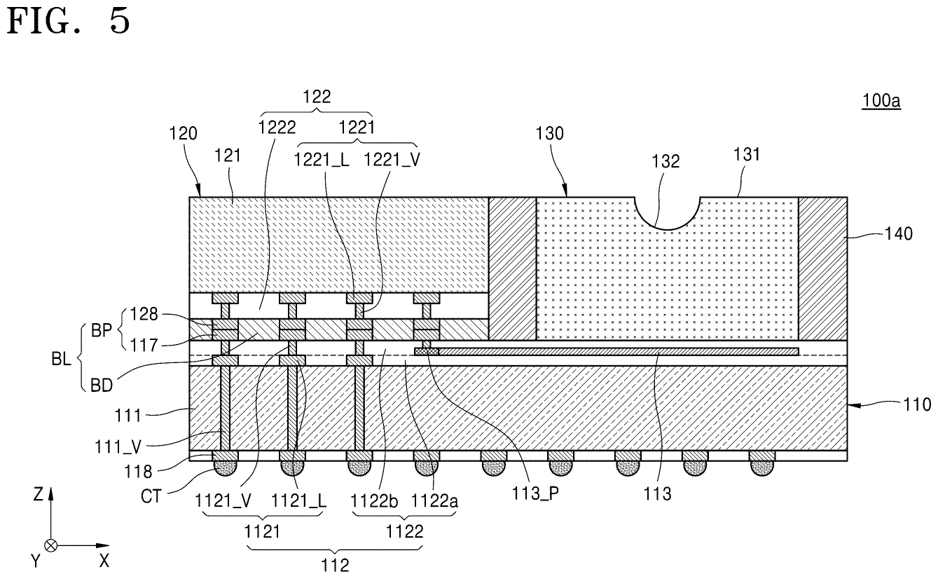

FIG. 5 is a cross-sectional view schematically showing a chip structure 100a according to an embodiment. Hereinafter, overlapping descriptions of the chip structure 100 described above with reference to FIGS. 3 and 4 and the chip structure 100a of FIG. 5 are omitted. Certain differences are described below.

As described above, the width of the EIC chip 120 may be less than that of the PIC chip 110. Referring to FIG. 5, the EIC chip 120 may be arranged so that one side surface of the EIC chip 120 aligns with one side surface of the PIC chip 110. Accordingly, the molding layer 140 may be disposed on the PIC chip 110 to surround the side surfaces of the optical block 130. However, the placement of the EIC chip 120 is not limited to this configuration, and may be modified so that the EIC chip 120 is entirely located on the upper surface of the PIC chip 110.

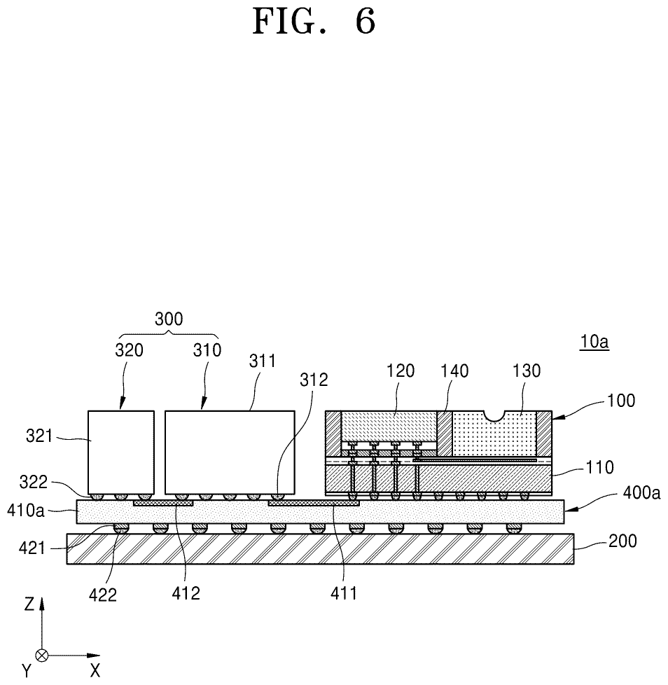

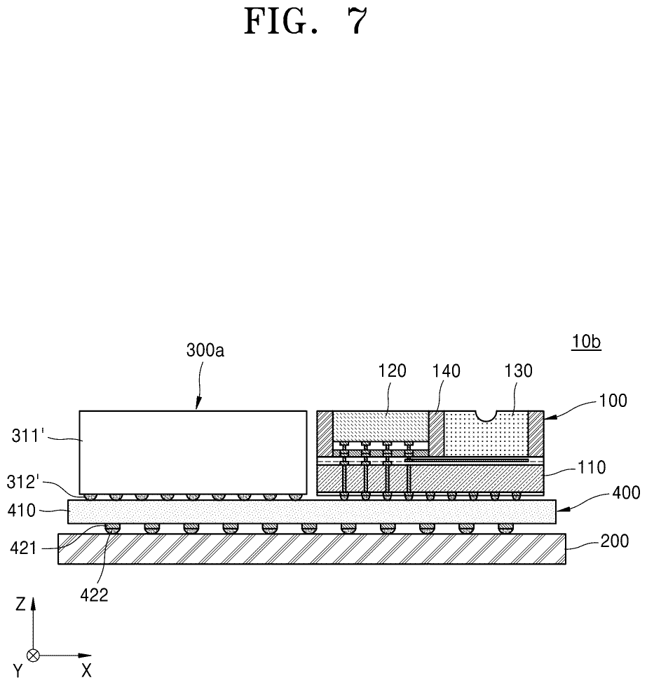

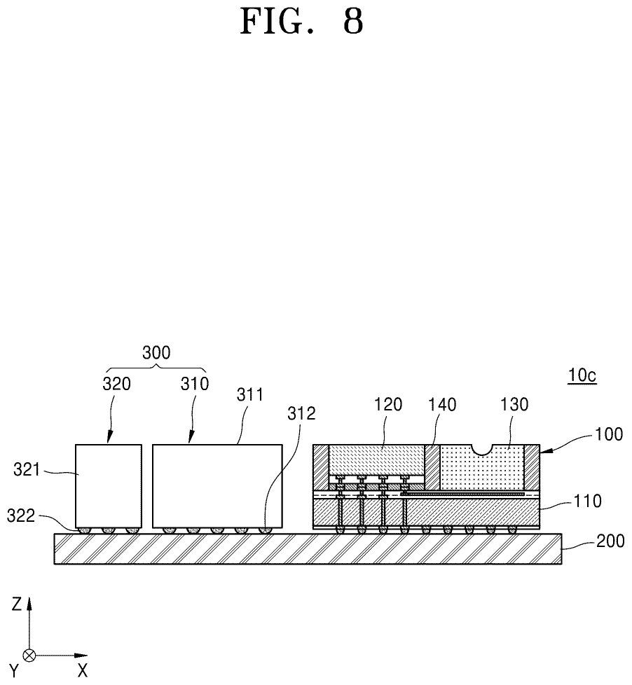

FIG. 6 is a cross-sectional view schematically showing a semiconductor package 10a according to an embodiment. FIG. 7 is a cross-sectional view schematically showing a semiconductor package 10b according to an embodiment. FIG. 8 is a cross-sectional view schematically showing a semiconductor package 10c according to an embodiment.

Most of the elements forming the semiconductor packages 10a, 10b, and 10c as well as the materials used in these elements are substantially the same as or similar to those described earlier with reference to FIGS. 1 to 4. Therefore, for convenience of description, certain differences between the semiconductor packages 10a, 10b, and 10c of FIGS. 6 to 8 and the semiconductor package 10 of FIG. 4 are described below.

Referring to FIG. 6, the semiconductor package 10a may include a second package substrate 400a disposed on the first package substrate 200. The first semiconductor chip 310, the second semiconductor chip 320, and the chip structure 100 may be mounted on an upper surface of the second package substrate 400a. The second package substrate 400a may electrically connect the first semiconductor chip 310, the second semiconductor chip 320, and the chip structure 100 to one another. The second package substrate 400a may electrically connect the first semiconductor chip 310, the second semiconductor chip 320, and the chip structure 100 to the first package substrate 200.

The second package substrate 400a may be a redistribution substrate 410a including a redistribution pattern and a redistribution insulating layer surrounding the redistribution pattern.

The redistribution insulating layer may include an insulating material, e.g., a photo-imageable dielectric (PID) resin. In some embodiments, the redistribution insulating layer may further include an inorganic filler. In some embodiments, the redistribution insulating layer may have a multi-layered structure with the redistribution pattern arranged in each layer.

The redistribution pattern may include a redistribution line pattern extending in the horizontal direction, and a redistribution via pattern extending vertically (Z-direction) from the redistribution line pattern. The redistribution line pattern may be disposed on at least one of the upper and lower surfaces of the redistribution insulating layer or in the redistribution insulating layer. The redistribution via pattern may be connected to a portion of the redistribution line pattern after passing through the redistribution insulating layer.

The redistribution pattern may include a conductive material, for example, copper (Cu), aluminum (Al), argentum (Ag), tin (Sn), aurum (Au), nickel (Ni), lead (Pb), titanium (Ti), or an alloy thereof.

The second package substrate 400a may further include a first silicon bridge 411 and a second silicon bridge 412. In some embodiments, the first silicon bridge 411 may be disposed on the upper surface of the redistribution substrate 410a and may electrically connect the first semiconductor chip 310 to the chip structure 100. A portion of the first silicon bridge 411 may be disposed in the second package substrate 400a. Some of the first connection terminals 312 of the first semiconductor chip 310 and some of the connection terminals CT of the chip structure 100 may contact the first silicon bridge 411. In some embodiments, the second silicon bridge 412 may electrically connect the first semiconductor chip 310 to the second semiconductor chip 320. The second silicon bridge 412 may be disposed on the upper surface of the redistribution substrate 410a, with portions thereof in the second package substrate 400a. Some of the first connection terminals 312 of the first semiconductor chip 310 and some of the second connection terminals 322 of the second semiconductor chip 320 may contact the second silicon bridge 412.

Referring to FIG. 7, one semiconductor chip 300a may be disposed in the semiconductor package 10b. The semiconductor chip 300a may be spaced apart from the chip structure 100 in the first horizontal direction (X-direction). The semiconductor chip 300a may include a semiconductor substrate 311′ with an active surface where a semiconductor device is formed, and a plurality of connection terminals 312′ disposed on the active surface of the semiconductor substrate 311′. The semiconductor chip 300a may be mounted on the second package substrate 400 via the plurality of connection terminals 312′ with its active surface facing downward.

When the semiconductor package 10b includes one semiconductor chip 300a, the semiconductor chip 300a may include a logic chip. For example, the semiconductor chip 300a may include an application processor (AP) such as a central processing unit (CPU), a graphics processing unit (CPU), a field-programmable gate array (FPGA), a digital signal processor, an encoding processor, a micro-processor, a micro controller, etc. In particular, for example, the semiconductor chip 300a may correspond to an application-specific IC (ASIC).

Referring to FIG. 8, in the semiconductor package 10c, the semiconductor chip 300 and the chip structure 100 may be directly mounted on the first package substrate 200. In other words, as compared with the semiconductor package 10 of FIG. 2, the second package substrate 400 may be omitted from the semiconductor package 10c of FIG. 8.

The first semiconductor chip 310, the second semiconductor chip 320, and the chip structure 100 may be mounted on the upper surface of the first package substrate 200. The first semiconductor chip 310 and the second semiconductor chip 320, spaced apart from each other in the first horizontal direction (X-direction), may be disposed on the first package substrate 200.

In FIG. 8, the first semiconductor chip 310, the second semiconductor chip 320, and the chip structure 100 are shown mounted on the first package substrate 200. However, the inventive concept is not limited to this configuration. For example, only one semiconductor chip and the chip structure 100 may be mounted on the first package substrate 200.

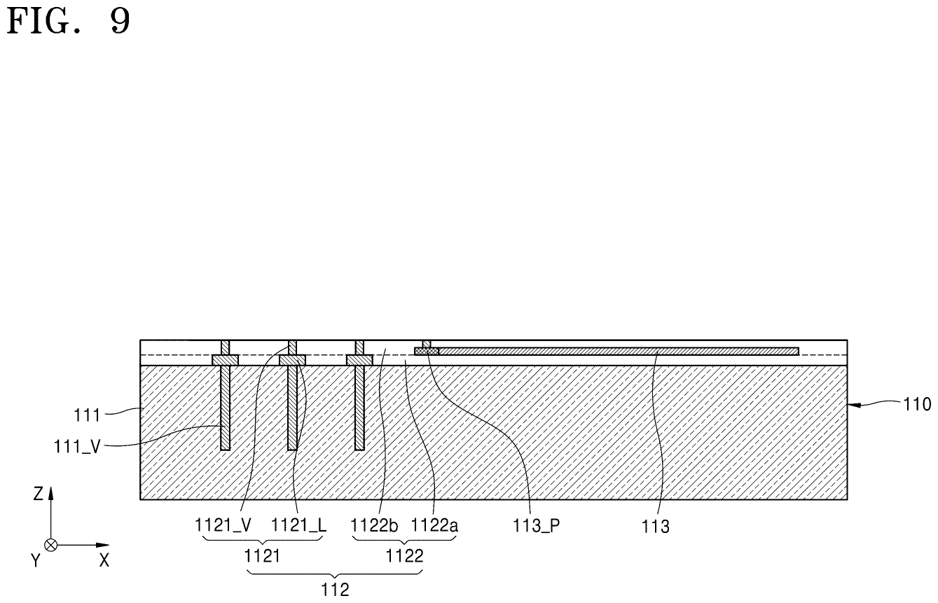

FIGS. 9 to 17 are diagrams schematically showing processes in a method of manufacturing the chip structure 100 according to FIG. 3.

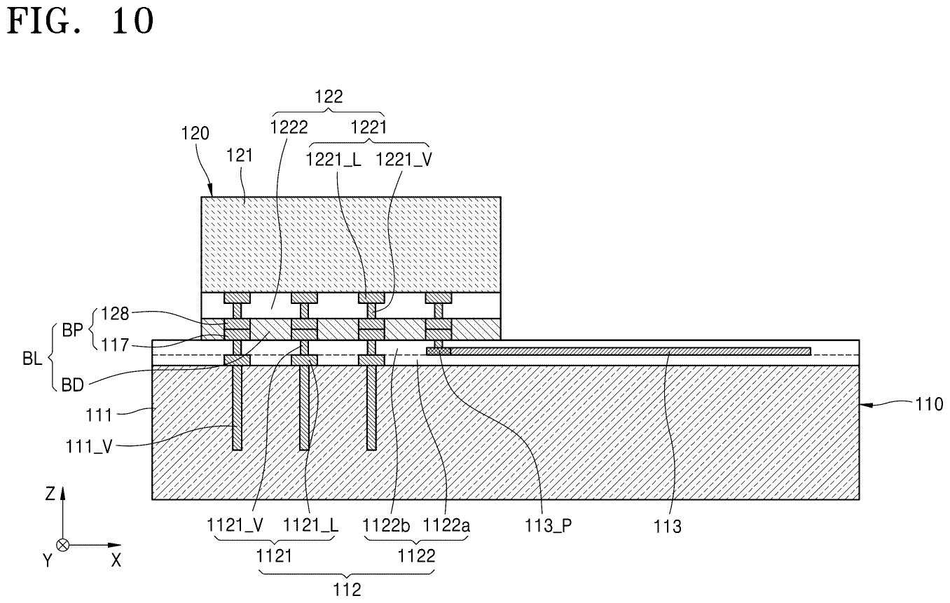

Referring to FIGS. 9 and 10, the PIC chip 110 is prepared, and the EIC chip 120 may be attached to the PIC chip 110. The PIC chip 110 may include the first substrate 111, and the first wiring structure 112 and the waveguide 113 that are located on the upper surface of the first substrate 111. The through-via 111_V extends in the first substrate 111 and may be connected to the first wiring structure 112. The EIC chip 120 may be attached to the PIC chip 110 in a face-down configuration, with the second wiring structure 122 of the EIC chip 120 facing the first wiring structure 112 of the PIC chip 110.

In some embodiments, the EIC chip 120 and the PIC chip 110 may be coupled using hybrid bonding. For example, the EIC chip 120 and the PIC chip 110 may be electrically connected via the bonding layer BL located between them.

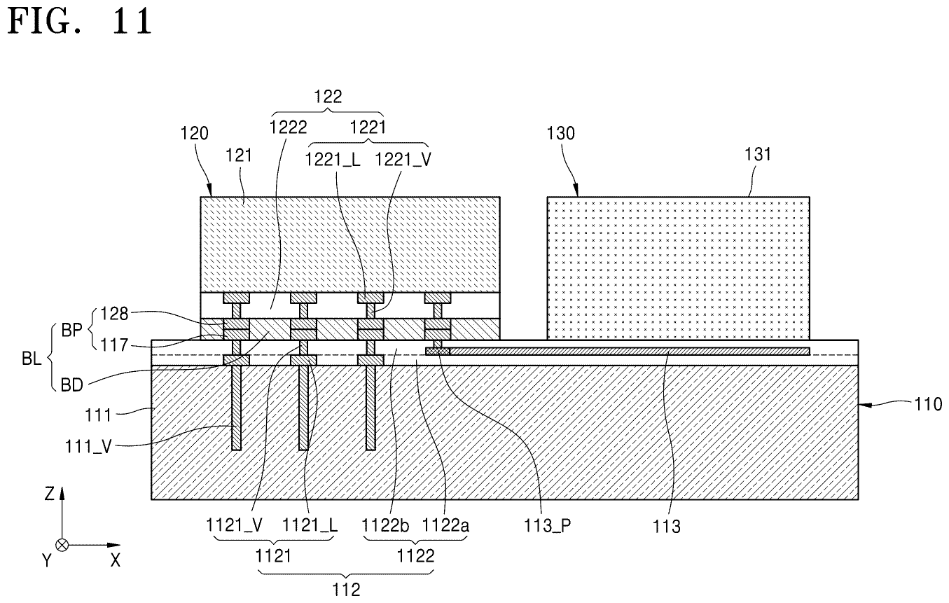

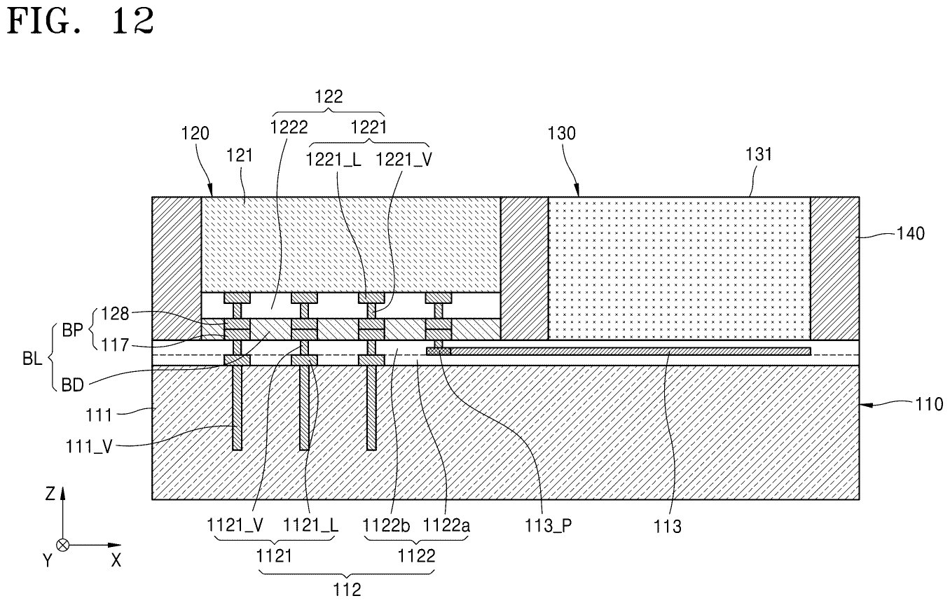

Referring to FIGS. 11 and 12, the optical block 130 is attached to the PIC chip 110, and the molding layer 140 is formed to surround the EIC chip 120 and the optical block 130.

The optical block 130 may be spaced apart from the EIC chip 120 in the first horizontal direction (X-direction) and attached to the PIC chip 110, located above the waveguide 113. For example, the optical block 130 may be coupled onto the PIC chip 110 using an oxide bonding method.

The upper surfaces of the EIC chip 120, the optical block 130, and the molding layer 140 may be formed to be coplanar. For example, the EIC chip 120, the optical block 130, and the molding layer 140 may be formed to a desired thickness using a grinding or a chemical mechanical polishing (CMP) process.

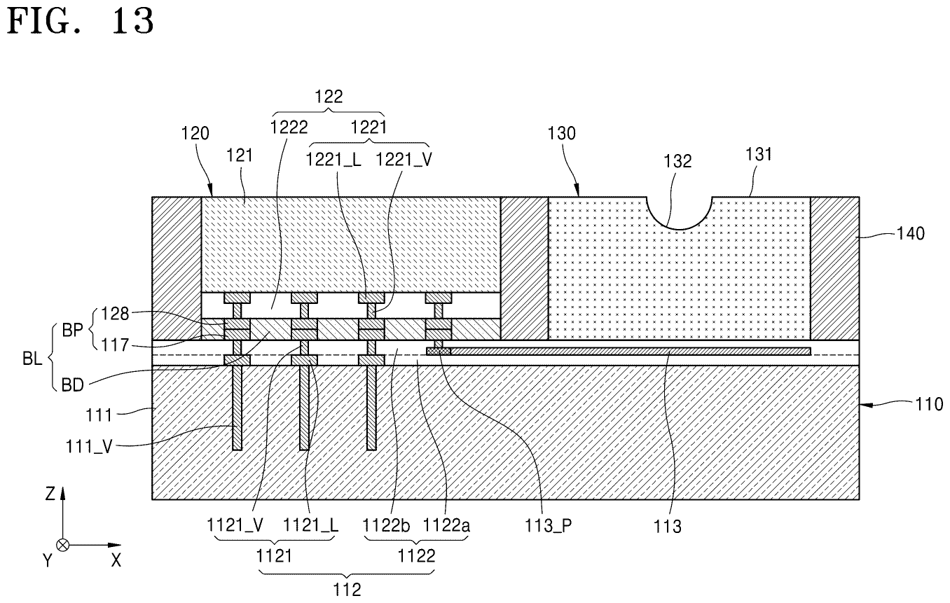

Referring to FIG. 13, the micro-lens 132 may be formed on the upper surface of the main body 131 of the optical block 130. The micro-lens 132 is positioned so that the external optical signal OS (see FIG. 4) can be directed to the waveguide 113 of the PIC chip 110 after passing through the interior of the main body 131.

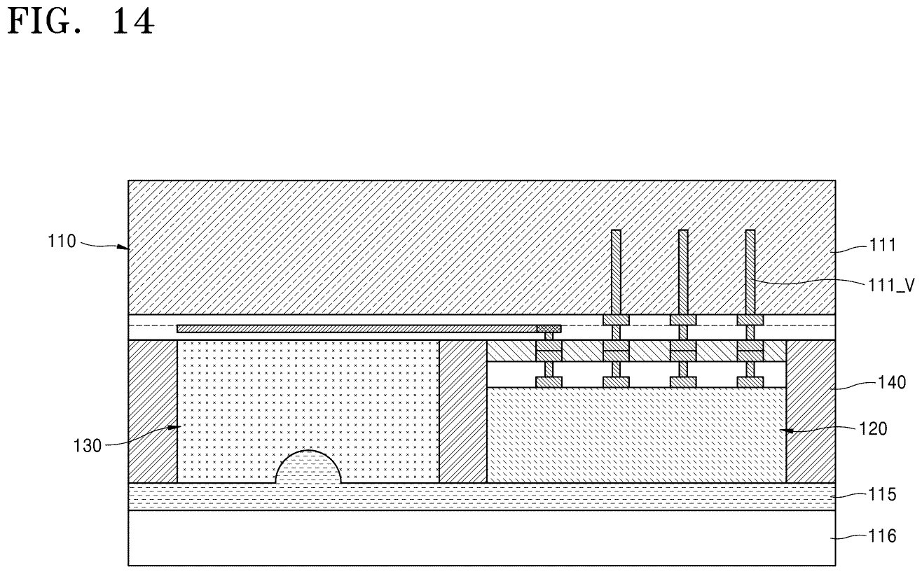

Referring to FIG. 14, the chip structure of FIG. 13 may be flipped over and attached to a carrier substrate 116. The chip structure may be attached to the carrier substrate 116 via a glue layer 115. For example, the carrier substrate 116 may be a glass substrate.

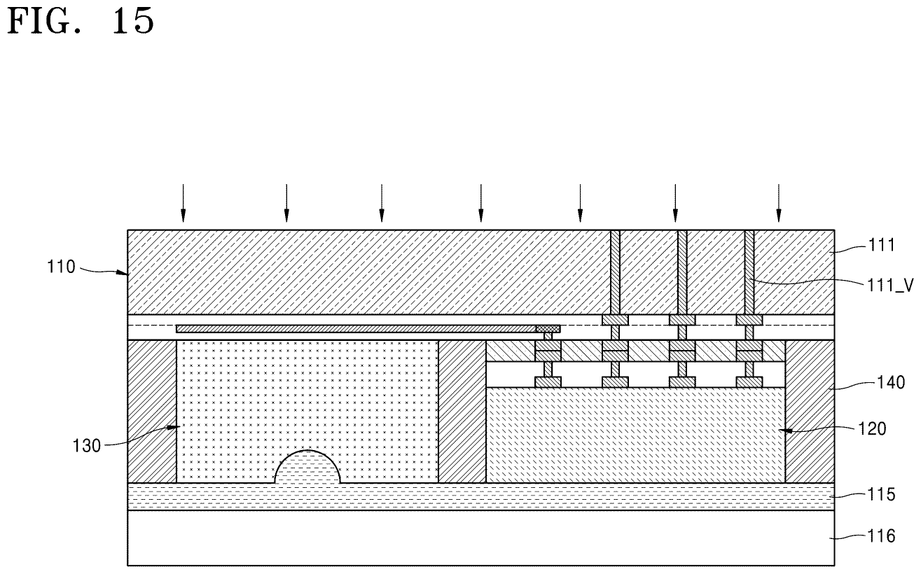

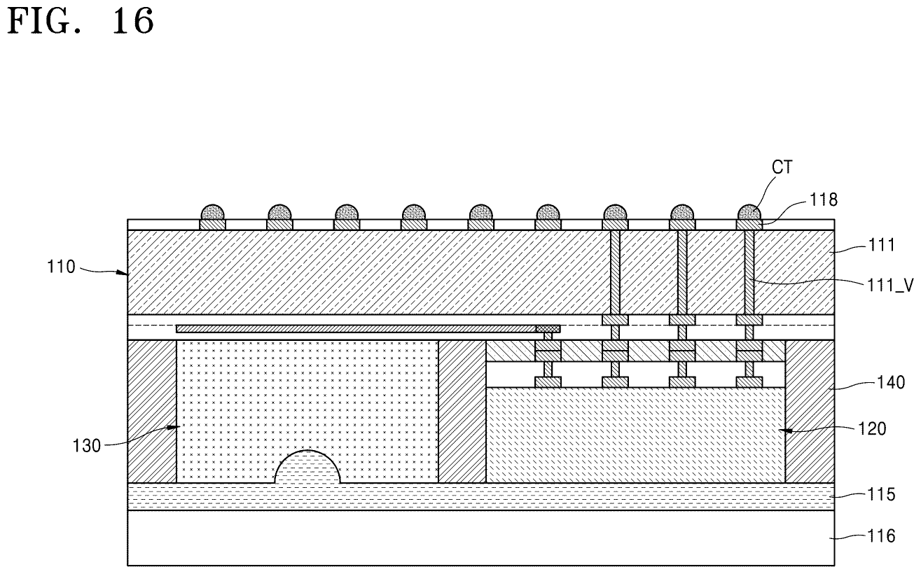

Referring to FIGS. 15 and 16, a back grinding process may be performed on the PIC chip 110 to reduce the thickness of the first substrate 111. When the through-via 111_V of the first substrate 111 is exposed during the back grinding process, the lower pads 118 and the connection terminals CT may be formed on the first substrate 111.

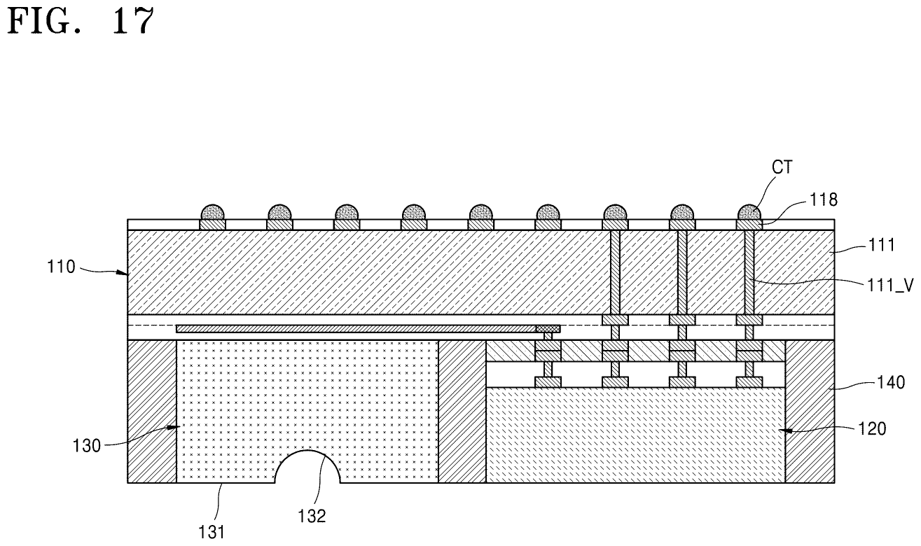

Referring to FIG. 17, the carrier substrate 116 (see FIG. 16) and the glue layer 115 (see FIG. 16) are removed to complete the chip structure 100.

The chip structure 100 may be mounted on the second package substrate 400 to manufacture the semiconductor package 10 of FIG. 2, with the connection terminals CT of the chip structure 100 positioned on the second package substrate 400. Additionally, the connection terminals CT of the chip structure 100 may be located on the first package substrate 200.

The chip structure 100 may be mounted on a package substrate to form the semiconductor package of FIGS. 2, and 5 to 8. In this configuration, the chip structure 100 is mounted so that the connection terminals CT are located on the package substrate. However, the application of the chip structure 100 is not limited to this arrangement, as it can also be used to form semiconductor packages in combination with various other elements.

While the inventive concept has been particularly shown and described with reference to embodiments thereof, it will be understood that various changes in form and detail may be made without departing from the spirit and scope of the following claims.

What is claimed is:

1. A chip structure comprising:
a photonic integrated circuit (PIC) chip;
an electronic integrated circuit (EIC) chip disposed on the PIC chip; and
an optical block disposed on the PIC chip, spaced apart from the EIC chip in a horizontal direction, and configured to transfer optical signals to the PIC chip.

2. The chip structure of claim 1, wherein the optical block includes silicon, glass, or polymer.

3. The chip structure of claim 1, wherein the chip structure is configured such that 98% or more of an optical path is formed within the optical block, with the optical signals being transferred to the PIC chip through the optical path.

4. The chip structure of claim 1, wherein the optical block is bonded to the PIC chip via oxide bonding.

5. The chip structure of claim 1, further comprising a micro-lens disposed on an upper surface of the optical block to direct the optical signals to the optical block.

6. The chip structure of claim 1, further comprising a molding layer disposed on the PIC chip and surrounding the optical block.

7. The chip structure of claim 6, wherein the molding layer includes an insulating material.

8. The chip structure of claim 6, wherein upper surfaces of the EIC chip, the optical block, and the molding layer are coplanar.

9. The chip structure of claim 1, wherein the PIC chip comprises:
a waveguide extending in the horizontal direction; and
a grating coupler configured to transfer the optical signals to the waveguide by controlling a direction of the optical signals incident through the optical block.

10. The chip structure of claim 1, wherein the EIC chip is electrically connected to the PIC chip via hybrid bonding.

11. A chip structure comprising:
a photonic integrated circuit (PIC) chip;
an electronic integrated circuit (EIC) chip disposed on the PIC chip;
an optical block disposed on the PIC chip, spaced apart from the EIC chip in a horizontal direction, and configured to transfer optical signals to the PIC chip; and
an insulating layer located between the optical block and the PIC chip, the insulating layer comprising a grating coupler configured to control a direction of the optical signals incident through the optical block and guide the optical signals into a waveguide formed in the PIC chip.

12. A semiconductor package comprising:
a substrate;
a semiconductor chip disposed on the substrate; and
a chip structure arranged on the substrate and spaced apart from the semiconductor chip in a horizontal direction, wherein the chip structure comprises:
a photonic integrated circuit (PIC) chip;
an electronic integrated circuit (EIC) chip disposed on the PIC chip; and
an optical block disposed on the PIC chip, spaced apart from the EIC chip in the horizontal direction, and configured to transfer optical signals to the PIC chip.

13. The semiconductor package of claim 12, wherein the optical block includes silicon, glass, or polymer.

14. The semiconductor package of claim 12, wherein the chip structure is configured such that 98% or more of an optical path is formed within the optical block, with the optical signals being transferred to the PIC chip through the optical path.

15. The semiconductor package of claim 12, wherein the optical block is bonded to the PIC chip via oxide bonding.

16. The semiconductor package of claim 12, wherein the PIC chip comprises:
a waveguide extending in the horizontal direction; and
a grating coupler configured to transfer the optical signals to the waveguide by controlling a direction of the optical signals incident through the optical block.

17. The semiconductor package of claim 12, further comprising a molding layer disposed on the PIC chip and surrounding the optical block, wherein upper surfaces of the EIC chip, the optical block, and the molding layer are coplanar.

18. The semiconductor package of claim 12, further comprising a package substrate disposed beneath the substrate;
wherein the substrate electrically connects the semiconductor chip and the chip structure to the package substrate.

19. The semiconductor package of claim 12, wherein the substrate is a silicon interposer.

20. The semiconductor package of claim 12, wherein the substrate is a redistribution substrate including a silicon bridge that electrically connects the semiconductor chip to the chip structure.
